(19) United States
(12) Patent Application Publication
(10) Pub. No.: US 2002/0135001 A1
(43) Pub. Date: Sep. 26, 2002

(54) Crosslinked resin and method for making oxides using same

(76) Inventor: Philippe Gaucher, Gif-Sur-Yvette (FR)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(21) Appl. No.: 10/069,951

(22) PCT Filed: Jul. 6, 2001
(86) PCT No.: PCT/FR01/02189

(30) Foreign Application Priority Data
Jul. 7, 2000 (FR) 00/08920

(51) Int. Cl. H01L 31/062; G03F 7/00; H01L 31/113; H01L 41/04; H01L 41/18; H01L 41/08; H01L 31/119; G03F 7/40

(52) U.S. Cl. 257/295; 430/198; 430/322; 430/330; 430/270.14; 522/148; 310/311; 310/367

(57) ABSTRACT

The invention relates to a crosslinked resin and to its application in the manufacture of ceramic or glass patterns at the surface of a substrate.

This resin is obtained from the mixing, in a solvent, of one or more simple metal alkoxides, complex metal alkoxides or silicon alkoxides, of acetylacetone and of hexamethylenetetramine, and then heating said mixture and exposing it to radiation.

Applications: ferroelectric memories, integrated capacitors, piezoelectric transducers.

The field of the invention is that of thin layer oxides and more specifically of oxides in the glass or ceramic form obtained by sol-gel processes.

Conventionally, the sol-gel process makes it possible, starting from a colloidal solution based on metal alkoxides or on silicon alkoxide, to manufacture powders or thin layers of oxides in the glass or ceramic form.

More specifically, the alkoxides are dissolved in a solvent and their hydrolysis leads to the condensation of polymeric networks of oxides and hydroxides. Nevertheless, it is not easy to control the degree and the kinetics of hydrolysis when synthesizing complex phases comprising a large number of components with different properties.

It is possible with difficulty to control simultaneously the chemical homogeneity which makes it possible to lower the synthesis temperature and the rheology, desirable for producing thin layer deposition.

It is possible to modify the viscosity and the elasticity of the solutions prepared by addition of agents, such as polyalcohols or polyacids, resulting in polymer resins. However, these additives are not necessarily compatible with cations and result in solutions with an adhesion to substrates which is not well suited to depositions, by centrifuging or by dipping, on substrates.

In this context, the Applicant Company has filed a patent application, published under the number 431 999, providing a process for the deposition of a ceramic composition as a thin layer starting from a homogeneous solution, the rheology of which can be adjusted to deposition by centrifuging or dipping. The cations are dissolved in a solution where polymerization (or maturation) is brought about by the reaction of two organic compounds: acetylacetone (ACAC) and hexamethylenetetramine (HMTA).

More specifically, these two compounds, brought into contact under hot conditions with an acid, result in a polymeric species. The combination thus formed is thus a binder comprising metal oxide grains.

This resin can subsequently be deposited on a substrate, to be brought to high temperature and to result in the production of a thin layer ceramic.

More specifically, the resin deposited on the substrate is first of all brought to a calcination temperature of the order of 500° C. During this operation, the solvent is evaporated and certain chemical entities are calcined to produce amorphous oxides.

A rapid annealing operation at approximately 700° C. is then carried out to produce the desired crystalline phase of the corresponding ceramic.

During the calcination operation, numerous stresses are generated due to the evaporation of the solvent and to the calcination of certain chemical compounds.

The invention provides for the use of a crosslinked resin which can be subsequently calcined, so as to reduce the stresses occasioned during this heating, for the manufacture of ceramic or of glass.

Furthermore, this crosslinked resin makes it possible to obtain in a very direct manner ceramic patterns with very small dimensions in comparison with the solutions of the prior art.

This is because the resin disclosed in Patent Application No. 431 999 can advantageously be exposed to ultraviolet radiation to result in a crosslinked resin with an improved performance.

This is why a subject matter of the invention is more specifically a crosslinked resin, characterized in that it comprises a material obtained from the mixing of one or more simple metal alkoxides, complex metal alkoxides or silicon alkoxides, of acetylacetone and of hexamethylenetetramine, and then heating said mixture and exposing it to radiation.

According to an alternative form of the invention, the simple metal alkoxides are of titanium alkoxide or zirconium alkoxide type.

According to another alternative form of the invention, the complex metal alkoxide is prepared from lead carboxylate, from titanium alkoxide and from zirconium alkoxide.

According to an alternative form of the invention, the mixture additionally comprises photoinitiating agents for enhancing the performance of the crosslinked resin obtained.

These agents can in particular be radical photoinitiators of Irgacure 184 or 1800 type from Ciba or alternatively benzophenone or diphenyl ketone.

According to an alternative form of the invention, the solvent is of 2-ethylhexanol and/or acetic acid type.

Another subject matter of the invention is a process for the manufacture of a ceramic or of a glass comprising:

the preparation of a solution of metal alkoxides in acetylacetone;

the production of a photosensitive resin by reaction under hot conditions of an acid and of hexamethylenetetramine with said solution;

the deposition of the photosensitive resin on a substrate;

the exposure of the photosensitive resin to ultraviolet radiation;

the calcination of the crosslinked resin.

The exposure of the photosensitive resin to ultraviolet radiation results in a denser gel and thus in thicker glass or ceramic oxide layers than according to the prior art.

According to an alternative form of the invention, the substrate is glass.

A further subject matter of the invention is a process for the manufacture of ceramic or glass patterns at the surface of a substrate, characterized in that:

exposure to radiation is carried out through a mask, so as to define radiation-exposed patterns and non-radiation-exposed patterns;

it comprises the dissolution of the non-radiation-exposed patterns in a solvent.

Such ceramic patterns are used in particular in such applications as ferroelectric memories, integrated capacitors, pyroelectric detectors for imaging or infrared detection, or piezoelectric sensors and Microsystems.

This is why a final subject matter of the invention is components of capacitor, piezoelectric transducer or piezoelectric memory type obtained from the process for the manufacture of a ceramic or of a glass according to the invention.

According to the prior art, it is possible to deposit a layer of oxide at the surface of a substrate by means of processes of cathodic sputtering type or a metalorganic chemical vapor deposition (MOCVD) process and then to define patterns on said layer of oxide by means of conventional photolithographic processes.

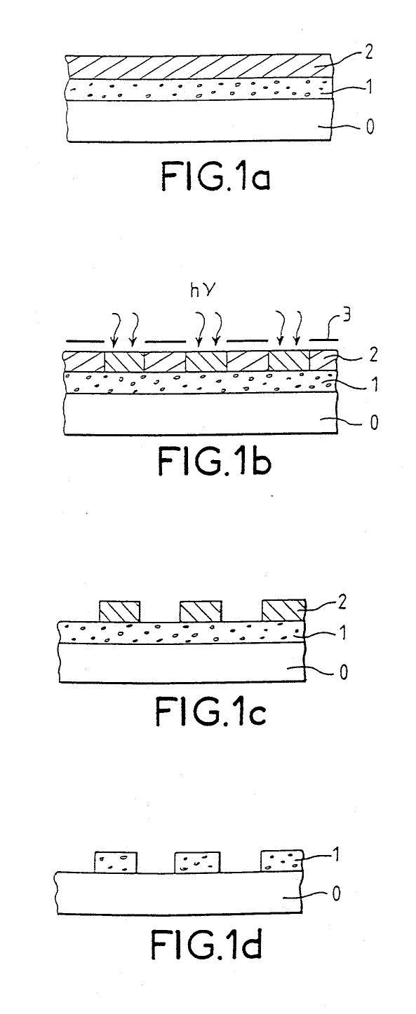

Thus, a photosensitive resin can be deposited at the surface of a ceramic layer prepared beforehand at the surface of a substrate. Said photosensitive resin is exposed to radiation through a mask and then the radiation-exposed or non-radiation-exposed resin (according to whether a negative or positive resin is involved) is dissolved using a solvent. The various stages of a photolithographic process which makes it possible to define ceramic patterns are illustrated in FIG. 1.

More specifically, FIG. 1a represents a ceramic layer 1 on a substrate 0, which substrate is covered with a layer of photosensitive resin 2. FIG. 1b diagrammatically represents the photosensitive resin 2 exposed to radiation through a mask 3. The radiation-exposed parts of the resin may become insoluble in some solvents, whereas the non-radiation-exposed parts remain soluble in said solvents. A mask is thus defined which makes it possible, for example, to etch the unmasked parts of FIG. 1c, with an acid of HCl/HF type in the case of a fine PZT layer, to produce the patterns illustrated in FIG. 1d. This chemical attack is isotropic and does not allow very fine resolution. Typically, it is difficult to produce patterns with a width of less than 10 μm.

The crosslinked resin according to the invention makes it possible to directly produce ceramic or glass patterns, dispensing with the need to use a masking resin and an isotropic etching process.

A better understanding of the invention will be achieved and other advantages will become apparent on reading the description which will follow, given without implied limitation, and by virtue of the appended figures, among which:

FIGS. 1a-1d illustrate the stages of a masking process according to the known art for defining ceramic patterns;

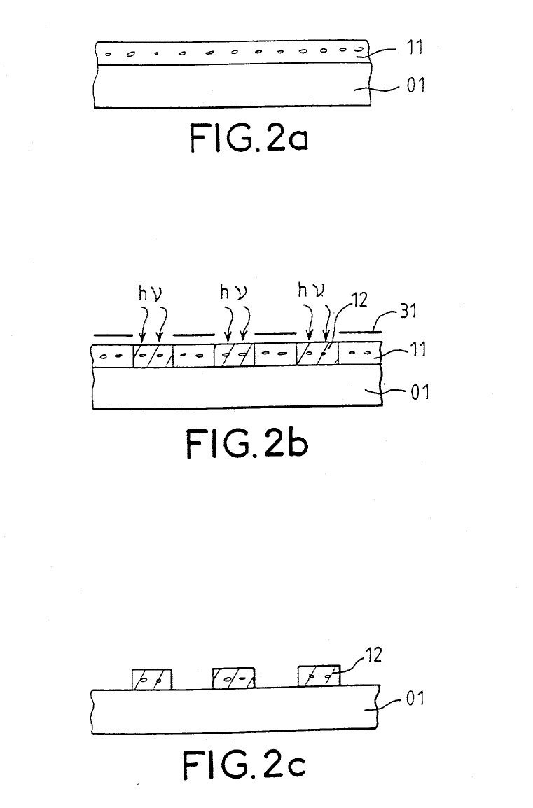

FIGS. 2a-2c illustrate the stages of a process according to the invention for defining ceramic patterns;

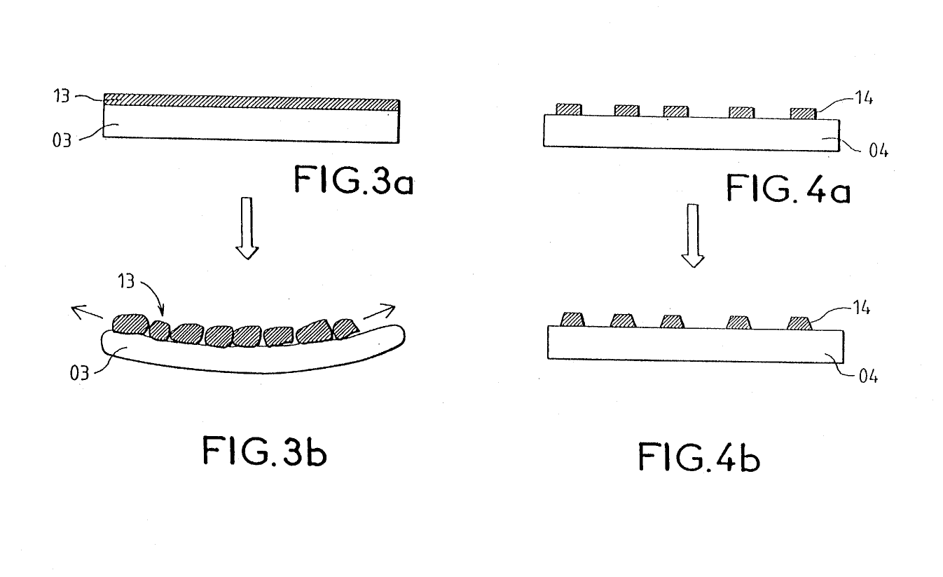

FIGS. 3a and 3b illustrate a layer of metal oxides with a thickness of a few microns on a silicon substrate, before and after sintering;

FIGS. 4a and 4b illustrate patterns formed from metal oxides with a thickness of a few microns on a silicon substrate, before and after sintering, obtained according to the invention.

A description will now be given of the invention in the context of an example of lead, zirconium and titanium (PZT) oxide but the invention applies just as well to the manufacture of silica or of refractory oxides, such as TiO₂ or ZiO₂.

First Stage:

Preparation of a Solution A Based on Metal Alkoxides

1 mol of lead 2-ethylhexanoate, 0.5 mol of zirconium n-butoxide and 0.5 mol of titanium n-butoxide are mixed at 60° C. A heavy carboxylate, 2-ethylhexanoate, is chosen in order to obtain a resin sufficiently viscous for a deposition on the substrate leading to a sufficient thickness.

The preceding mixture is brought together with acetylacetone in a proportion of 1 mol of ACAC per mole of Pb.

A solvent of heavy alcohol type, for example 2-ethylhexanol, can advantageously be added thereto to adjust the viscosity of said solution.

A solution A based on lead, zirconium and titanium oxides and on ACAC is thus obtained.

Second Stage:

Preparation of a Solution B Based on HMTA

At the same time, the mixture of 0.5 mol of hexamethylenetetramine (HMTA) in the presence of 100 cm³ of acetic acid is prepared at 60° C. It is just as possible to replace acetic acid with propanoic acid or trifluoroacetic acid.

Third Stage:

Preparation of a Photosensitive Resin Based on Metal Alkoxides

The solutions A and B are brought together and are heated to form the resin.

Typically, heating can be carried out at 118° C. for approximately 15 minutes. The higher the temperature, the more viscous the resin.

A PZT resin is thus obtained in which the grains of PZT oxides are taken up in a polymer matrix formed from HMTA and ACAC.

Fourth Stage:

Exposure to Radiation of the Photosensitive Resin to Form the Crosslinked Resin

The resin 11 formed in stage 3 can typically have a kinematic viscosity of the order of 25 centistokes and be deposited by conventional centrifuging or dipping means at the surface of a substrate 01 (FIG. 2a).

The resin is then exposed to ultraviolet radiation, typically at 335 nm, making it possible to densify the resin and to render it insoluble to certain solvents, including dilute acetic acid and/or 2-ethylhexanol.

Exposure to radiation can advantageously be carried out through a mechanical mask 31, so as to define soluble patterns 11 and insoluble patterns 12 in the resin layer (FIG. 2b).

It is particularly advantageous to define patterns formed from oxides prior to the firing or sintering stage corresponding to densification. The patterns soluble in 2-ethylhexanol and/or acetic acid are subsequently removed to leave in place only the insoluble patterns 12 (FIG. 2c).

This is because, according to the processes of the prior art, resin layers above a thickness of the order of 2 microns, deposited on plaques with a diameter of approximately 10 cm, for example, have a tendency to fail during the sintering stage because of the stresses generated between the layer and the substrate during the decrease in volume related to the change from a porous gel to a dense oxide. For the same reasons, the substrate can have a tendency to bend.

When the patterns are defined photochemically in the resin layer before sintering, the stresses are decreased for two reasons:

the starting gel is denser because of the ultraviolet radiation;

the area under which these stresses are exerted is smaller and the stresses can release over the edges of the pattern, as illustrated in FIGS. 3 and 4, which respectively represent, FIGS. 3a and 3b, an oxide layer 13 with a thickness of a few microns on a silicon substrate 03, before sintering and after sintering, and, FIGS. 4a and 4b, patterns formed from oxides 14 prepared beforehand, with a thickness of a few microns, on a silicon substrate 04, before sintering and after sintering.

Typically, the ceramic patterns thus defined without deformation can just as easily have dimensions of less than a few microns as dimensions of a few tens, indeed even a few hundreds, of microns.

This is because, according to the invention, the stages of photolithography, exposure to radiation and then dissolution make it possible in particular to obtain very fine patterns, in contrast to the ceramic isotropic chemical etching operations of the prior art.

1. A crosslinked resin, characterized in that it comprises a material obtained from the mixing of at least one or more simple metal alkoxides, complex metal alkoxides or silicon alkoxides, of acetylacetone, of hexamethylenetetramine and of an acid, and then heating said mixture and exposing it to radiation.

2. The crosslinked resin as claimed in claim 1, characterized in that the metal alkoxide is of titanium alkoxide type.

3. The crosslinked resin as claimed in claim 2, characterized in that the metal alkoxide is of zirconium alkoxide type.

4. The crosslinked resin as claimed in claim 1, characterized in that it comprises a complex lead/zirconium and titanium alkoxide.

5. The crosslinked resin as claimed in claim 4, characterized in that the complex lead, zirconium and titanium alkoxide is obtained from lead carboxylate, zirconium alkoxide and titanium alkoxide.

6. The crosslinked resin as claimed in one of claims 1 to 5, characterized in that the acid is acetic acid.

7. The crosslinked resin as claimed in one of claims 1 to 5, characterized in that the acid is propanoic acid.

8. The crosslinked resin as claimed in one of claims 1 to 5, characterized in that the acid is trifluoroacetic acid.

9. The crosslinked resin as claimed in one of claims 1 to 8, characterized in that it additionally comprises at least one photoinitiating agent.

10. A process for the manufacture of a ceramic or of a glass, comprising:
the preparation of a solution of simple metal alkoxides, complex metal alkoxides or silicon oxides in acetylacetone;
the production of a resin by reaction under hot conditions of an acid and of hexamethylenetetramine with said solution;
the deposition of the resin on a substrate;
the exposure of the resin to ultraviolet radiation;
the calcination of the radiation-exposed resin, in order to obtain the ceramic or the glass.

11. The process for the manufacture of a ceramic or of a glass as claimed in claim 10, characterized in that the solution of simple metal alkoxides, complex metal alkoxides or silicon alkoxides is prepared in the presence of a heavy alcohol of 2-ethylhexanol type.

12. The process for the manufacture of ceramic or of glass as claimed in either of claims 10 and 11, characterized in that the simple metal alkoxides are zirconium alkoxide or titanium alkoxide.

13. The process for the manufacture of ceramic or of glass as claimed in either of claims 10 and 11, characterized in that it comprises a stage of preparation of complex metal alkoxides from lead carboxylate, zirconium alkoxide and titanium alkoxide.

14. The process for the manufacture of ceramic or glass patterns at the surface of a substrate as claimed in one of claims 10 to 13, characterized in that:
exposure to radiation is carried out through a mask, so as to define radiation-exposed patterns and non-radiation-exposed patterns;
it comprises the dissolution of the non-radiation-exposed patterns in a solvent.

15. The process for the manufacture of ceramic or glass patterns as claimed in claim 14, characterized in that the solvent is of dilute acetic acid and/or 2-ethylhexanol type.

16. The process for the manufacture of a ceramic or of a glass as claimed in one of claims 10 to 15, characterized in that the substrate is glass.

17. The process for the manufacture of a ceramic or of a glass as claimed in one of claims 10 to 15, characterized in that the substrate is silicon.

18. A capacitor, characterized in that it is obtained from the process for the manufacture of a ceramic or of a glass as claimed in one of claims 10 to 15.

19. A piezoelectric transducer, characterized in that it is obtained from the process for the manufacture of a ceramic or of a glass as claimed in one of claims 10 to 15.

20. A ferroelectric memory, characterized in that it is obtained from the process for the manufacture of a ceramic or of a glass as claimed in one of claims 10 to 15.
